(19) United States
(12) Patent Application Publication
(10) Pub. No.: US 2012/0007497 A1
(43) Pub. Date: Jan. 12, 2012

(54) ORGANIC LIGHT EMITTING DEVICE

(75) Inventors: Chang-Ho Lee, Yongin-city (KR); Hee-Joo Ko, Yongin-city (KR); Il-Soo Oh, Yongin-city (KR); Se-Jin Cho, Yongin-city (KR); Hyung-Jun Song, Yongin-city (KR); Jin-Young Yun, Yongin-city (KR); Jong-Hyuk Lee, Yongin-city (KR)

(73) Assignee: Samsung Mobile Display Co., Ltd., Yongin-city (KR)

(21) Appl. No.: 13/178,047

(22) Filed: Jul. 7, 2011

(30) Foreign Application Priority Data
Jul. 9, 2010 (KR) 10-2010-0066392

(51) Int. Cl. H01J 1/63; H01L 33/60

(52) U.S. Cl. 313/504; 257/98; 257/E33.072

(57) ABSTRACT

An organic light emitting device is disclosed. The organic light emitting device includes: a substrate member; and an organic light emitting diode comprising a first transparent electrode, a first organic emission layer, a conductive reflecting layer, a second organic emission layer, and a second transparent electrode that are sequentially stacked over the substrate member, wherein voltage is applied between the first transparent electrode and the second transparent electrode to allow each of the first transparent electrode and the second transparent electrode to maintain first potential and second potential, and the conductive reflecting layer maintains third potential between the first potential and the second potential.

### CROSS-REFERENCE TO RELATED APPLICATIONS

This application claims priority to and the benefit of Korean Patent Application No. 10-2010-0066392 filed in the Korean Intellectual Property Office on Jul. 9, 2010, the entire contents of which are incorporated herein by reference.

### BACKGROUND

1. Field

The described technology relates generally to an organic light emitting device, and more particularly, to a double-sided emission type organic light emitting device that emits light to the top and bottom of a substrate member.

2. Description of the Related Technology

A display device and a light device using an organic light emitting diode that is a self light emitting device has been known. Unlike the liquid crystal display (LCD), the organic light emitting diode (OLED) display does not require a separate light source, thereby making it possible to be implemented as a slim and lightweight display. Further, the organic light emitting diode (OLED) display has high-quality characteristics such as low power consumption, high luminance, rapid response speed, and the like, such that it has been widely applied from small mobile devices to home appliances with large-sized displays.

The organic light emitting device generally includes a substrate member and an organic light emitting diode formed on the substrate member. The organic light emitting diode typically includes a first electrode, an organic emission layer, and a second electrode that are sequentially stacked over the substrate member. When the first electrode is transparent and the second electrode is reflective, the organic light emitting device is referred to as a bottom emission type. When the first electrode is reflective and the second electrode is transparent, the organic light emitting device is referred to as a top emission type.

The information disclosed in this Background section is only for enhancement of understanding of the background of the described technology and therefore it may contain information that does not form prior art that is already known in this country to a person of ordinary skill in the art.

### SUMMARY OF CERTAIN INVENTIVE ASPECTS

The described technology has been made in an effort to provide a double-sided emission type organic light emitting device displaying a high-luminance screen similar to a top emission type and a bottom emission type, and/or emitting high-luminance light.

One aspect is an organic light emitting device, including: i) a substrate member; and ii) an organic light emitting diode including a first transparent electrode, a first organic emission layer, a conductive reflecting layer, a second organic emission layer, and a second transparent electrode that are sequentially stacked over the substrate member. Voltage is applied between the first transparent electrode and the second transparent electrode to allow each of the first transparent electrode and the second transparent electrode to maintain first potential and second potential, and the conductive reflecting layer maintains third potential between the first potential and the second potential.

The first potential may be larger than the third potential and the third potential may be larger than the second potential. The first transparent electrode may have a work function larger than that of the conductive reflecting layer and the conductive reflecting layer may have a work function larger than that of the second transparent electrode.

The first transparent electrode may include indium tin oxide, indium zinc oxide, zinc oxide, aluminum zinc oxide, indium oxide, or combination thereof.

The conductive reflecting layer may include any one of silver (Ag), silver alloy, aluminum (Al), and aluminum alloy and the conductive reflecting layer has a thickness of between about 50 nm and about 150 nm.

The second transparent electrode may include silver (Ag), silver alloy, aluminum (Al), aluminum alloy, indium oxide, zinc oxide, aluminum zinc oxide, gallium zinc oxide, indium zinc oxide or combination thereof.

The second transparent electrode may be formed of a stacked layer made of a metal including silver (Ag), silver alloy, aluminum (Al), aluminum alloy or combination thereof and a metal oxide including indium oxide, zinc oxide, aluminum zinc oxide, gallium zinc oxide, indium zinc oxide or combination thereof.

The second transparent electrode may have a thickness of between about 10 nm and about 20 nm.

The organic light emitting diode may further include an electron injection layer that is positioned either between the first organic emission layer and the conductive reflecting layer or between the second organic emission layer and the second transparent electrode. The electron injection layer may include at least one selected from lithium fluoride (LiF), barium fluoride (BaF), and cesium fluoride (CsF) and at least one selected from aluminum (Al), ytterbium (Yb), and calcium (Ca).

The organic light emitting diode may further include the hole injection layer that is positioned between the conductive reflecting layer and the second organic emission layer and the hole injection layer may include at least one of a dipole layer and a p-type doped organic layer.

The dipole layer may include at least one of, for example, fullerene (C60), oxide tungsten (WO3), oxide molybdenum (MoO3) and hexadecafluorophthalocyanine (F16CuPc).

The first organic emission layer and the second organic emission layer may be formed of any one of a red emission layer, a green emission layer, and a blue emission layer. The organic light emitting diode may be provided in plural and the organic light emitting device may further include a plurality of driving circuit units. The first transparent electrode may be electrically connected to the driving circuit unit and the second transparent electrode may be formed over the plurality of organic light emitting diodes.

The first organic emission layer and the second organic emission layer may be each formed in a multilayer of first layers and second layers that have the relationship of complementary colors. The first organic emission layer and the second organic emission layer may be each formed of a multilayer of a red emission layer, a green emission layer, and a blue emission layer.

Another aspect is an organic light emitting device, including: a base substrate, an encapsulation substrate, and an organic light emitting diode, positioned between the base and encapsulation substrates, the organic light emitting diode including: a first transparent electrode, a second transparent electrode, a conductive reflecting layer positioned between the first and second transparent electrodes, a first organic emission layer positioned between the first transparent electrode and the conductive reflecting layer, a second organic emission layer positioned between the second transparent electrode and the conductive reflecting layer, wherein the conductive reflecting layer is configured to reflect light emitted from the first and second organic emission layers.

The first transparent electrode may be positioned over the base substrate and the second transparent electrode may be positioned over the encapsulation substrate.

The conductive reflecting layer may be configured to reflect light emitted from the first emission layer toward the base substrate and light emitted from the second organic emission layer toward the encapsulation substrate.

According to some embodiments, the high-luminance display screen or the light emitting surface can be simultaneously implemented in the bottom direction toward the substrate member and the top direction toward the encapsulation substrate. In addition, the structures of the organic light emitting device and the associated circuitry may be simplified.

### BRIEF DESCRIPTION OF THE DRAWINGS

FIG. 1 is a configuration diagram of an embodiment of an organic light emitting device;

FIG. 2 is a layout view of an embodiment of an organic light emitting diode display;

FIG. 3 is a cross-sectional view taken along line II-II the organic light emitting diode display of FIG. 2;

FIG. 4 is a cross-sectional view an embodiment of an organic light emitting lighting device; and

FIG. 5 is a cross-sectional view of another embodiment of an organic light emitting lighting device.

### DETAILED DESCRIPTION OF CERTAIN INVENTIVE EMBODIMENTS

Certain embodiments will be described more fully hereinafter with reference to the accompanying drawings. As those skilled in the art would realize, the described embodiments may be modified in various ways without departing from the spirit or scope of the present invention.

The drawings and description are to be regarded as illustrative in nature and not restrictive. Like reference numerals generally designate like elements throughout the specification. The size and thickness of each component shown in the drawings are arbitrarily shown for understanding and ease of description, but embodiments are not limited thereto.

In the specification, it will be understood that when an element such as a layer, film, region, or substrate is referred to as being “on” another element, it can be directly on the other element or intervening elements may also be present.

Recently, a double-sided emission type organic light emitting device that emits light to both the top and bottom substrate members has been researched. The double-sided emission type organic light emitting includes a first electrode and a second electrode formed of transparent conductive material. As a result, the light emitted from the organic emission layer is emitted to both sides while transmitting both of the first electrode and the second electrode.

However, the above-mentioned double-sided emission type organic light emitting device has a structure that disperses the light emitted from the organic emission layer to both of the first electrode and the second electrode. Therefore, when the double-sided emission type organic light emitting device is electrically driven, a display screen or light viewed from the top or bottom side has lower luminance compared to a top emission type or a bottom emission type organic light emitting device.

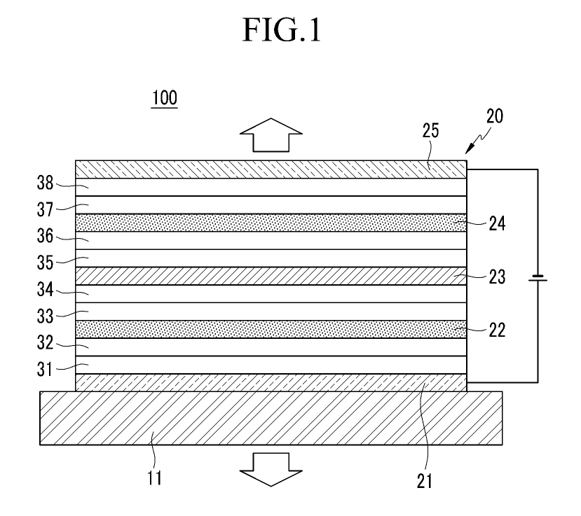

FIG. 1 is a configuration diagram of an embodiment of an organic light emitting device.

Referring to FIG. 1, an embodiment of an organic light emitting device 100 includes a substrate member 11 and an organic light emitting diode 20 formed on the substrate member 11. The organic light emitting diode 20 includes a first transparent electrode 21, a first organic emission layer 22, a conductive reflecting layer 23, a second organic emission layer 24, and a second transparent electrode 25 that are sequentially stacked over the substrate member 11.

The substrate member 11 is made of a transparent insulating material. In some embodiments, the substrate member 11 may be made of any one of glass, quartz, ceramic, polymer resin, and the like. The organic light emitting device 100 may include an encapsulation substrate (not shown) or a thin encapsulation layer (not shown) that covers and protects the organic light emitting diode 20.

The first organic emission layer 22 and the second organic emission layer 24 are stacked along the thickness direction of the substrate member 11 and the conductive reflecting layer 23 is positioned between the first organic emission layer 22 and the second organic emission layer 24. The conductive reflecting layer 23 is a floating electrode to which voltage is not applied from the outside. The first transparent electrode 21 and the second transparent electrode 25 are positioned on outermost sides of the organic light emitting diode 20.

In the embodiment of an organic light emitting device 100 of FIG. 1, a driving voltage is applied between the first transparent electrode 21 and the second transparent electrode 25. The first transparent electrode 21 maintains a first potential and the second transparent electrode 25 maintains a second potential. The conductive reflecting layer 23 maintains a third potential between the first potential and the second potential.

In some embodiments, the first potential may be larger than the second potential. In such embodiments, the third potential is smaller than the first potential and larger than the second potential. In such embodiments, the first organic emission layer 22 and the first transparent electrode 21 serve as a hole injection electrode, and the conductive reflecting layer 23 serves as an electron injection electrode. The second organic emission layer 24 and the conductive reflecting layer 23 serve as the hole injection electrode and the second transparent electrode 25 serves as the electron injection electrode.

The organic light emitting device may include a plurality of organic light emitting diodes 20 and a plurality of thin film transistors (not shown) to drive the plurality of organic light emitting diodes. The first transparent electrode 21 is electrically connected to the corresponding thin film transistor such that it may be supplied with the driving voltage therefrom. On the other hand, the second transparent electrode may be formed over the plurality of organic light emitting diodes and may be supplied with common voltage.

The first transparent electrode 21 is made of a transparent conducting material having a high work function, and the second transparent electrode 25 is made of a transparent conducting material having a low work function. The conductive reflecting layer 23 serves as both of the electron injection electrode and the hole injection electrode and is made of a reflective conductive material having a lower work function than the first transparent electrode 21 and a higher work function than the second transparent electrode 25.

The first transparent electrode 21 may be made of a metal oxide. In some embodiments, the first transparent electrode 21 may include indium tin oxide, indium zinc oxide, zinc oxide, aluminum zinc oxide, indium oxide, or a combination thereof.

The second transparent electrode 25 may be made of metal or metal oxide. In some embodiments, the second transparent electrode 25 may include silver (Ag), silver alloy, aluminum (Al), aluminum alloy, indium oxide, zinc oxide, aluminum zinc oxide, gallium zinc oxide, indium zinc oxide or a combination thereof. In some embodiments, the silver alloy may include silver and ytterbium (Yb).

In other embodiments, the second transparent electrode 25 may be formed of a stacked layer made of a metal including silver (Ag), silver alloy, aluminum (Al), aluminum alloy or a combination thereof and a metal oxide including indium oxide, zinc oxide, aluminum zinc oxide, gallium zinc oxide, indium zinc oxide or a combination thereof.

The second transparent electrode 25 is formed to have a thickness of about 20 nm or less in order to have light transmittance of about 70% or more. If the thickness of the second transparent electrode 25 is less than about 10 nm, the electrical resistance of the second transparent electrode 25 is increased and thus, the thickness of the second transparent electrode 25 may be between about 10 nm and about 20 nm.

The conductive reflecting layer 23 may include any one of silver (Ag), aluminum (Al), silver alloy, and aluminum alloy, and may be formed to have a thickness of about 50 nm or more in order to reflect light.

In the embodiment of FIG. 1, the first organic emission layer 22 and the second organic emission layer 24 simultaneously emit light. The light emitted from the first organic emission layer 22 is reflected by the conductive reflecting layer 23 and transmitted through the first transparent electrode 21 and the substrate member 11 and is then emitted to the outside of the organic light emitting device 100. The light emitted from the second organic emission layer 24 is reflected by the conductive reflecting layer 23 and transmitted through the second transparent electrode 25 and is then emitted to the outside of the organic light emitting device 100.

Embodiments of the organic light emitting device 100 serving as double-sided emission type devices concentrate light from the first organic emission layer 22 and from the second organic emission layer 24 by the light reflecting action of the conductive reflecting layer 23, thereby improving the luminance of the display screen or the light emitting surface. The first organic emission layer 22 and the second organic emission layer 24 can simultaneously emit light without voltage being separately applied to the conductive reflecting layer 23, thereby simplifying the structures of the organic light emitting device 100 and the associated circuitry.

The first organic emission layer 22 and the second organic emission layer 24 can emit light having the same luminance or one of the emission layers can emit light having a slightly larger luminance. In embodiments with one of the organic emission layers emitting light with a larger luminance, the side with the emission layer having the larger luminance may be used as the main display screen or the main light emitting surface, and the other side with the emission layer having the lower luminance can be used as the sub-display screen or the sub-light emitting surface.

At least one of a first hole injection layer 31 and a first hole transport layer 32 may be positioned between the first transparent electrode 21 and the first organic emission layer 22. At least one of a first electron transport layer 33 and a first electron injection layer 34 may be positioned between the first organic emission layer 22 and the conductive reflective layer 23.

The first electron injection layer 34 may include at least one material selected from lithium fluoride (LiF), barium fluoride (BaF), and cesium fluoride (CsF), and at least one material selected from aluminum (Al), ytterbium (Yb), and calcium (Ca).

The first electron injection layer 34 may be formed in a single layer or a multi layer structure. In embodiments of a single layer structure, the first electron injection layer 34 may be made of a mixture of at least one selected from, for example, lithium fluoride (LiF), barium fluoride (BaF), and cesium fluoride (CsF) and at least one selected from aluminum (Al), ytterbium (Yb), and calcium (Ca). In embodiments of a multi layer structure, the first electron injection layer 34 may include a layer including at least one material selected from, for example, lithium fluoride (LiF), barium fluoride (BaF), and cesium fluoride (CsF), and a stacked layer including at least one material selected from aluminum (Al), ytterbium (Yb), and calcium (Ca).

At least one of a second hole injection layer 35 and a second hole transport layer 36 may be positioned between the conductive reflecting layer 23 and the second organic emission layer 24. At least one of a second electron transport layer 37 and a second electron injection layer 38 may be positioned between the second organic emission layer 24 and the second transparent electrode 25.

The second hole injection layer 35 may include at least one of a dipole layer and a p-type doped organic layer. The dipole layer and the p-type doped organic layer help reduce the energy barrier blocking the movement of electrons moving from the opposite side while facilitating hole injection, thereby improving the efficiency. The dipole layer may include at least one of, for example, fullerene (C60), oxide tungsten (WO₃), oxide molybdenum (MoO3) and hexadecafluorophthalocyanine (F16CuPc).

In some embodiments, the second electron injection layer 38 may be formed of the same materials as the above-mentioned first electron injection layer 34.

An organic light emitting diode display and an organic light emitting lighting device using an embodiment of an organic light emitting device 100 is described below.

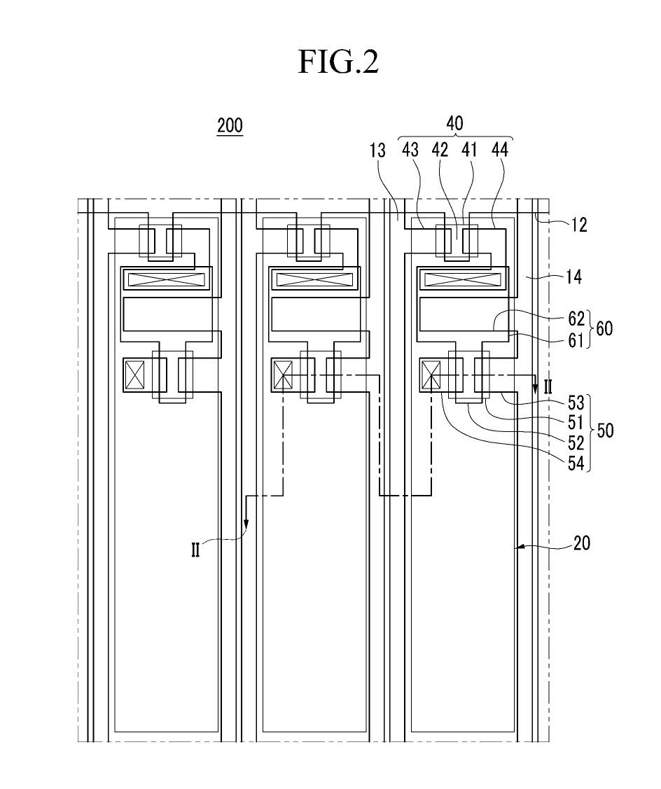

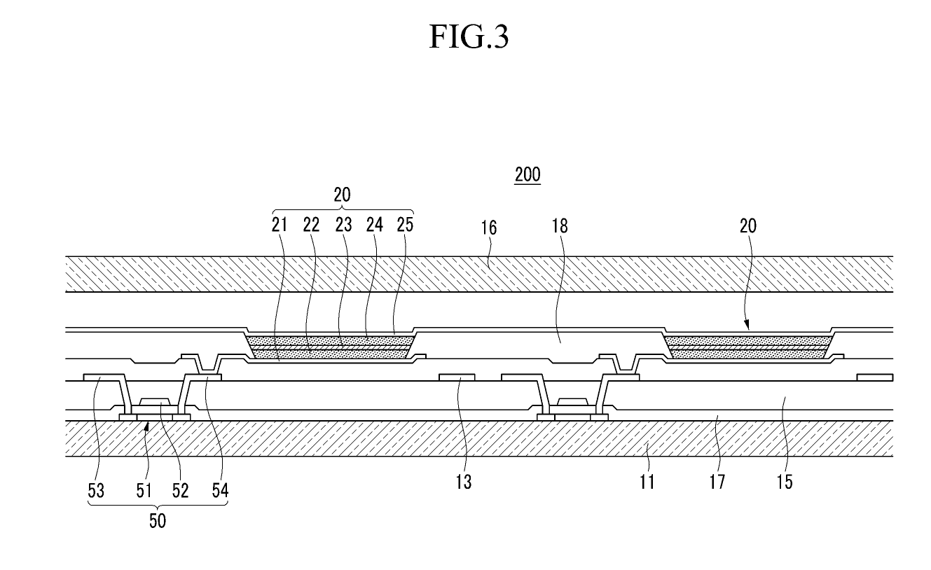

FIG. 2 is a layout view of an embodiment of an organic light emitting diode display and FIG. 3 is a cross-sectional view taken along line II-II the organic light emitting diode display of FIG. 2.

Referring to FIGS. 2 and 3, an organic light emitting diode (OLED) display 200 includes a switching thin film transistor 40, a driving thin film transistor 50, a capacitor 60, and an organic light emitting diode 20, for each pixel. The organic light emitting diode display 200 further includes a gate line 12 disposed along one direction and a data line 13 intersecting with the data line 12 in an insulating state, and a common voltage line 14.

In some embodiments, one pixel may be defined by a boundary of the gate line 12, the data line 13, and the common voltage line 14. Each pixel may include one subpixel or a plurality of subpixels, and is the minimum unit for displaying images.

The organic light emitting diode 20 includes the first transparent electrode 21, the first organic emission layer 22, the conductive reflecting layer 23, the second organic emission layer 24, and the second transparent electrode 25 that are sequentially stacked over the substrate member 11. The first transparent electrode 21 and the conductive reflecting layer 23 are formed respectively for each pixel, and the second transparent electrode 25 is commonly formed over the plurality of pixels. In some embodiments, the conductive reflecting layer 23 is not an electrode to which voltage is applied from the outside and is positioned between the first organic emission layer 22 and the second organic emission layer 24 without being connected to the external line.

As described above, for the first organic emission layer 22, the first transparent electrode 21 becomes the hole injection electrode and the conductive reflecting layer 23 becomes the electron injection electrode. For the second organic emission layer 24, the conductive reflecting layer 23 becomes the hole injection electrode and the second transparent electrode 25 becomes the electron injection electrode. The holes and electrons from the first transparent electrode 21 and the conductive reflecting layer 23, respectively, are injected into the first organic emission layer 22 and the holes and electrons from the conductive reflecting layer 23 and the second transparent electrode 25, respectively, are injected into the second organic emission layer 24. When excitons formed by the combination of the injected holes and electrons fall from the excited state to the ground state, light is emitted.

The capacitor 60 includes a first capacitor plate 61 and a second capacitor plate 62 with an interlayer insulating layer 15 therebetween. The interlayer insulating layer 15 is made of a dielectric material. The capacitance is determined by the charges stored in the capacitor 60 and the voltage between the first and the second capacitor plates 61 and 62.

A switching thin film transistor 40 includes a switching semiconductor layer 41, a switching gate electrode 42, a switching source electrode 43, and a switching drain electrode 44. A driving thin film transistor 50 includes a driving semiconductor layer 51, a driving gate electrode 52, a driving source electrode 53, and a driving drain electrode 54.

The switching thin film transistor 40 is used as a switching device to Selecta pixel to emit light. The switching gate electrode 42 is connected to the gate line 12. The switching source electrode 43 is connected to the data line 13. The switching drain electrode 44 is spaced apart from the switching source electrode 43 and is connected to the first capacitor plate 61.

The driving thin film transistor 50 applies the driving voltage for light-emitting the first and second organic emission layers 22 and 24 of the selected pixel to the first transparent electrode 21. The driving gate electrode 52 is connected to the first capacitor plate 61 and the driving source electrode 53 and the second capacitor plate 62 are connected to the common voltage line 14. The driving drain electrode 54 is connected to the first transparent electrode 21 of the organic light emitting diode 20 through a contact hole.

In some embodiments, the switching thin film transistor 40 is operated by a scan voltage applied to the gate line 12 to transfer the data voltage applied to the data line 13 to the driving thin film transistor 50. The voltage corresponding to the difference between the common voltage applied to the driving thin film transistor 50 from the common voltage line 14 and the data voltage transferred from the switching thin film transistor 40 is stored in the capacitor 60. The current corresponding to the voltage stored in the capacitor 60 flows from the organic light emitting diode 20 through the driving thin film transistor 50, thereby light emitting the first and second organic emission layers 22 and 24.

Referring to FIG. 3, an encapsulation substrate 16 covers and protects the organic light emitting diode 20 and a gate insulating layer 17 insulates the driving semiconductor layer 51 from the driving gate electrode 52. Further, reference numeral 18 represents a pixel defining layer.

The first organic emission layer 22 and the second organic emission layer 24 positioned in each pixel may both be made of a material emitting the same light emitting color. The first organic emission layer 22 and the second organic emission layer 24 may be formed of any one of a red emission layer, a green emission layer, and a blue emission layer. In some embodiments, the organic light emitting diode display 200 can simultaneously display a high luminance full-color screen in the bottom direction toward the substrate member 11 and the top direction toward the encapsulation substrate 16.

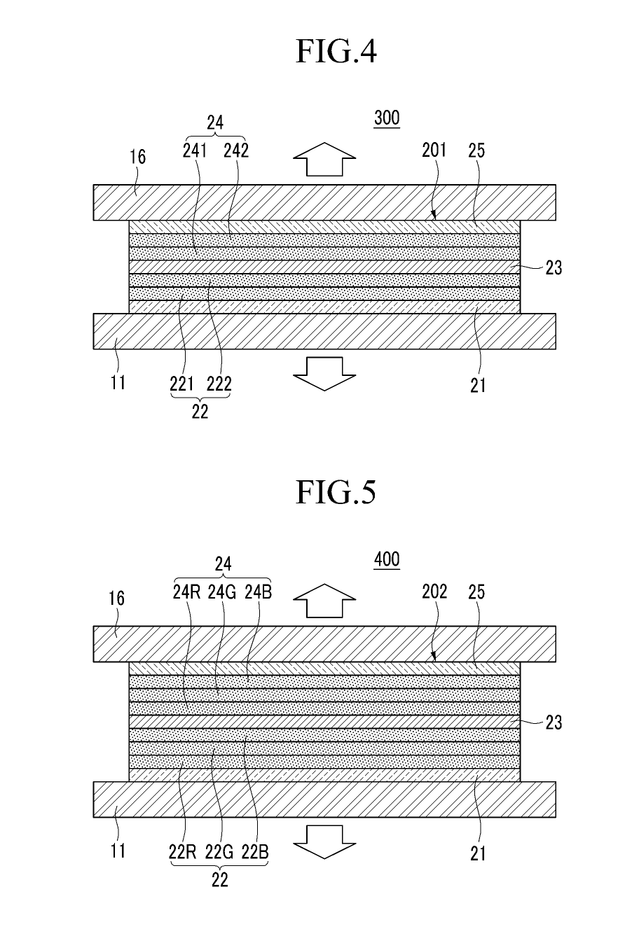

FIG. 4 is a cross-sectional view an embodiment of an organic light emitting lighting device.

Referring to FIG. 4, an embodiment of the organic light emitting lighting device 300 includes the substrate member 11 and an organic light emitting diode 201 formed over the substrate member 11. The organic light emitting diode 201 includes the first transparent electrode 21, the first organic emission layer 22, the conductive reflecting layer 23, the second organic emission layer 24, and the second transparent electrode 25 that are sequentially stacked over the substrate member 11. The first organic emission layer 22 and the second organic emission layer 24 are each formed in a multilayer of first layers 221 and 241 and second layers 222 and 242 respectively, which have a relationship of complementary colors. In some embodiments, the first layers 221 and 241 may be an orange emission layer and the second layers 222 and 242 may be a skyblue emission layer. In such embodiments, the organic light emitting lighting device 300 can simultaneously emit high luminance white light in the bottom direction toward the substrate member 11 and the top direction toward the encapsulation substrate 16.

FIG. 5 is a cross-sectional view of another embodiment of an organic light emitting lighting device.

Referring to FIG. 5, the first organic emission layer 22 and the second organic emission layer 24 of the organic light emitting diode 202 are each formed in a multilayer of red emission layers 22R and 24R, green emission layers 22G and 24G, and blue emission layers 22B and 24B, respectively. In such embodiments, the organic light emitting lighting device 400 can simultaneously emit high luminance white light in the bottom direction toward the substrate member 11 and the top direction toward the encapsulation substrate 16.

In some embodiments, the organic light emitting lighting devices 300 and 400 emit white light, as described above. In other embodiments, the organic light emitting lighting devices 300 and 400 can implement other light emitting colors according to the materials of the first organic emission layer 22 and the second organic emission layer 24.

In some embodiments, the first organic emission layer 22 and the second organic emission layer 24 may be made of materials emitting light emitting colors different from one another. In such embodiments, the organic light emitting lighting device can emit light having different colors in the bottom direction toward the substrate member 11 and the top direction toward the encapsulation substrate 16.

While this disclosure has been described in connection with certain embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting device, comprising:
a substrate member; and
an organic light emitting diode comprising a first transparent electrode, a first organic emission layer, a conductive reflecting layer, a second organic emission layer, and a second transparent electrode that are sequentially stacked over the substrate member,
wherein voltage is applied between the first transparent electrode and the second transparent electrode to allow each of the first transparent electrode and the second transparent electrode to maintain first potential and second potential, and
the conductive reflecting layer maintains third potential between the first potential and the second potential.

2. The organic light emitting device of claim 1, wherein:
the first potential is larger than the third potential and the third potential is larger than the second potential.

3. The organic light emitting device of claim 2, wherein:
the first transparent electrode has a work function larger than that of the conductive reflecting layer, and the conductive reflecting layer has a work function larger than that of the second transparent electrode.

4. The organic light emitting device of claim 3, wherein:
the first transparent electrode comprises at least one of indium tin oxide, indium zinc oxide, zinc oxide, aluminum zinc oxide, indium oxide, and a combination thereof.

5. The organic light emitting device of claim 3, wherein:
the conductive reflecting layer comprises at least one of silver (Ag), silver alloy, aluminum (Al), and aluminum alloy.

6. The organic light emitting device of claim 5, wherein:
the conductive reflecting layer has a thickness of between about 50 nm and about 150 nm.

7. The organic light emitting device of claim 3, wherein:
the second transparent electrode comprise at least one of silver (Ag), silver alloy, aluminum (Al), aluminum alloy, indium oxide, zinc oxide, aluminum zinc oxide, gallium zinc oxide, indium zinc oxide and a combination thereof.

8. The organic light emitting device of claim 7, wherein:
the second transparent electrode comprises a stacked layer made of a metal comprising at least one of silver (Ag), silver alloy, aluminum (Al), aluminum alloy and a combination thereof, and a metal oxide comprising at least one of indium oxide, zinc oxide, aluminum zinc oxide, gallium zinc oxide, indium zinc oxide and a combination thereof.

9. The organic light emitting device of claim 7, wherein:
the second transparent electrode has a thickness of between about 10 nm and about 20 nm.

10. The organic light emitting device of claim 3, wherein:
the organic light emitting diode comprises an electron injection layer positioned either between the first organic emission layer and the conductive reflecting layer or between the second organic emission layer and the second transparent electrode,
wherein the electron injection layer comprises at least one of lithium fluoride (LiF), barium fluoride (BaF), and cesium fluoride (CsF), and at least one of aluminum (Al), ytterbium (Yb), and calcium (Ca).

11. The organic light emitting device of claim 3, wherein:
the organic light emitting diode further comprises a hole injection layer positioned between the conductive reflecting layer and the second organic emission layer,
wherein the hole injection layer comprises at least one of a dipole layer and a p-type doped organic layer.

12. The organic light emitting device of claim 11, wherein:
the dipole layer comprises at least one of fullerene (C60), oxide tungsten (WO3), oxide molybdenum (MoO3) and hexadecafluorophthalocyanine (F16CuPc).

13. The organic light emitting device of any one of claim 1, wherein:
the first organic emission layer and the second organic emission layer are each formed of at least one of a red emission layer, a green emission layer, and a blue emission layer.

14. The organic light emitting device of claim 13, further comprising:
a plurality of organic light emitting diodes and a plurality of thin film transistors,
wherein the first transparent electrode is electrically connected to one of the plurality of thin film transistors, and the second transparent electrode is formed over the plurality of organic light emitting diodes.

15. The organic light emitting device of any one of claim 1, wherein:
the first organic emission layer and the second organic emission layer each comprises a first layer and a second layer, wherein the first and second layers have the relationship of complementary colors to one another.

16. The organic light emitting device of any one of claim 1, wherein:
the first organic emission layer and the second organic emission layer each comprises a red emission layer, a green emission layer, and a blue emission layer.

17. An organic light emitting device, comprising:
a base substrate;
an encapsulation substrate; and
an organic light emitting diode, positioned between the base and encapsulation substrates, the organic light emitting diode comprising:
a first transparent electrode;
a second transparent electrode;
a conductive reflecting layer positioned between the first and second transparent electrodes;
a first organic emission layer positioned between the first transparent electrode and the conductive reflecting layer;
a second organic emission layer positioned between the second transparent electrode and the conductive reflecting layer,
wherein the conductive reflecting layer is configured to reflect light emitted from the first and second organic emission layers.

18. The device of claim 17, wherein the first transparent electrode is positioned over the base substrate and the second transparent electrode is positioned over the encapsulation substrate.

19. The device of claim 18, wherein the conductive reflecting layer is configured to reflect light emitted from the first emission layer toward the base substrate and light emitted from the second organic emission layer toward the encapsulation substrate.
